(19) United States
(12) Patent Application Publication
(10) Pub. No.: US 2011/0149672 A1
(43) Pub. Date: Jun. 23, 2011

(54) SEMICONDUCTOR INTEGRATED CIRCUIT DEVICE

(75) Inventor: Kouhei Fukuoka, Osaka (JP)

(73) Assignee: PANASONIC CORPORATION, Osaka (JP)

(21) Appl. No.: 13/037,779

(22) Filed: Mar. 1, 2011

Related U.S. Application Data
(63) Continuation of application No. PCT/JP2009/003236, filed on Jul. 10, 2009.

(30) Foreign Application Priority Data
Dec. 25, 2008 (JP) 2008-329533

(51) Int. Cl. G11C 5/14

(52) U.S. Cl. 365/226

(57) ABSTRACT

A semiconductor integrated circuit device includes: a circuit required to be in a data retaining state; a data retention characteristic evaluation circuit configured to measure the data retaining state of the circuit; a leakage current evaluation circuit configured to measure the leakage current in the circuit; a voltage control signal generation circuit configured to control a voltage supply circuit for the circuit; and a memory circuit configured to store measurement results of the leakage current evaluation circuit and the data retention characteristic evaluation circuit. The voltage control signal generation circuit sets, for the voltage supply circuit, a voltage with which the leakage current in the circuit is minimized, based on data stored in the memory circuit.

### CROSS-REFERENCE TO RELATED APPLICATION

This is a continuation of PCT International Application PCT/JP2009/003236 filed on Jul. 10, 2009, which claims priority to Japanese Patent Application No. 2008-329533 filed on Dec. 25, 2008. The disclosures of these applications including the specifications, the drawings, and the claims are hereby incorporated by reference in their entirety.

### BACKGROUND

The present disclosure relates to a technology of improving data retention, and also reducing the leakage current, during power supply control and substrate control of a semiconductor chip.

In recent years, as semiconductor integrated circuits have been increasingly miniaturized, the problem that the leakage current of semiconductor chips greatly affects the electric power has begun to come to the surface. As means of reducing the leakage current, power supply control and substrate control techniques are known, in which the power supply voltage and the substrate voltage are controlled, while data in a flipflop and a memory is retained, in a standby state where circuit operation is not especially required, thereby to reduce the leakage current that steadily flows to a transistor. Incidentally, if data retention is not necessary, a technique of cutting off power supply will be effective.

In the above power supply control and substrate control techniques, the optimum voltage value varies with the finished state of the chip. For example, if a high reverse bias is applied to the substrate of a chip finished to have a high threshold (Vt) in the process, the subthreshold leakage will decrease but the junction leakage will increase, resulting in increase in total leakage current. The optimum voltage value also varies with the temperature state. Thus, applying the same substrate voltage value uniformly for all chips and for any temperature state may decrease the leakage current reduction effect, or even produce a reverse effect of increasing the leakage current depending on the finished state of the chip.

As a measure against the above problem, WO 2003/094235 (Patent Document 1) describes a technique in which the obtained voltage Vt of each chip is monitored, and the bias applied to the substrate is varied with the finished state and temperature state of the chip. In this technique, first, the obtained voltage Vt of a chip is measured during testing, and the result is stored in a nonvolatile data retention circuit inside the chip. From the obtained voltage Vt and temperature information, the substrate voltage is set to a value with which the leakage current is minimized, thereby to reduce the leakage current.

Japanese Patent Publication No. 2007-311763 (Patent Document 2) discloses a technique in which occurrence of a malfunction is constantly monitored on an actual circuit in the normal operation state and the standby state, thereby to permit setting of a voltage value optimum for the finished state of the chip and the temperature state.

### SUMMARY

In the technique of Patent Document 1, the finished state of the chip is checked indirectly via a monitor circuit, not using the circuit characteristics of the actual object to be controlled. Therefore, it is difficult to set an optimum voltage with which the leakage current is minimized. Moreover, at the application of the substrate voltage, whether data retention is guaranteed with the voltage is not determined. Therefore, there is a possibility of corruption of data that must be retained.

In the technique of Patent Document 2, since occurrence of a malfunction of the object circuit to be controlled is monitored, it is guaranteed that the set voltage permits data retention. However, once a malfunction occurs, it is necessary to carry out the same processing again, resulting in decrease in throughput. Moreover, this voltage setting does not necessarily provide an optimum voltage for the leakage current characteristic.

In view of the problems described above, there are presented various example embodiments of the present invention, which permit setting of an optimum power supply voltage and substrate voltage with which data retention is improved and the leakage current is minimized for individual semiconductor chips.

The semiconductor integrated circuit device of an embodiment of the present invention includes: a circuit required to be in a data retaining state; a data retention characteristic evaluation circuit configured to measure the data retaining state of the circuit; a leakage current evaluation circuit configured to measure a leakage current in the circuit; a voltage control signal generation circuit configured to control a voltage supply circuit for the circuit; and a memory circuit configured to store measurement results of the leakage current evaluation circuit and the data retention characteristic evaluation circuit, wherein the voltage control signal generation circuit sets, for the voltage supply circuit, a voltage with which the leakage current in the circuit is minimized, based on data stored in the memory circuit.

The data retention characteristic evaluation circuit determines whether data retention is possible (or good) or not (or poor) with each of a plurality of voltage values applied to the circuit, and the leakage current evaluation circuit measures the leakage current with each of the plurality of voltage values. By the above evaluation, it is possible to set a voltage value with which the data retention is improved and moreover the leakage current is minimized. The set voltage value is stored in the memory circuit, and the voltage control signal generation circuit controls the voltage supply circuit based on the stored voltage value, thereby permitting application of the voltage value with which the leakage current is minimized to the circuit. Thus, the present invention implements a means of setting a voltage value with which the leakage current is minimized while data retention is improved, which was conventionally unavailable. Also, in the above configuration, the data retention characteristic and leakage current characteristic of the circuit that retains data are directly acquired for setting a voltage value. Thus, the present invention provides an ideal voltage setting means that is less wasteful than the conventional means of indirectly acquiring a voltage value from measurement results of a monitor circuit.

The voltage value set by the voltage control signal generation circuit in the embodiment of the present invention for the voltage supply circuit and applied to the circuit may be a source-drain voltage (hereinafter referred to as a power supply voltage).

The voltage value set by the voltage control signal generation circuit in the embodiment of the present invention for the voltage supply circuit and applied to the circuit may be a source-substrate voltage (hereinafter referred to as a substrate voltage). For further reduction in leakage current, it is preferable to have both power supply voltage and substrate voltage supply circuits.

In the semiconductor integrated circuit device of the embodiment of the present invention, the data retention characteristic evaluation circuit may be placed in a region different from the semiconductor integrated circuit device, and transfer a data retention characteristic to the memory circuit from the different region.

With the above configuration, the area of the semiconductor integrated circuit device can be reduced by the portion of the data retention characteristic evaluation circuit.

In the semiconductor integrated circuit device of the embodiment of the present invention, the leakage current evaluation circuit may be placed in a region different from the semiconductor integrated circuit device, and transfers a leakage current characteristic to the memory circuit from the different region.

With the above configuration, the area of the semiconductor integrated circuit device can be reduced by the portion of the leakage current evaluation circuit.

In the semiconductor integrated circuit device of the embodiment of the present invention, the data retention characteristic evaluation circuit and the leakage current evaluation circuit may be placed in a region different from the semiconductor integrated circuit device, and transfers a data retention characteristic and a leakage current characteristic to the memory circuit from the different region.

With the above configuration, the area of the semiconductor integrated circuit device can be reduced by the portion of the data retention characteristic evaluation circuit and the leakage current evaluation circuit.

In the semiconductor integrated circuit device of the embodiment of the present invention, the voltage supply circuit may be placed in a region different from the semiconductor integrated circuit device.

With the above configuration, the area of the semiconductor integrated circuit device can be reduced by the portion of the voltage supply circuit.

The semiconductor integrated circuit device of the embodiment of the present invention may have a plurality of voltage supply circuits, and the entire of the plurality of voltage supply circuits may be placed in the same region as, or a different region from, the semiconductor integrated circuit device, or otherwise some of the plurality of voltage supply circuits may be placed on the same region while the remainder being placed in a different region.

When the plurality of voltage supply circuits are placed in the same region as the semiconductor integrated circuit device, the voltage value can be supplied with low impedance, compared with the case of being placed in a different region. When the plurality of voltage supply circuits are placed in a different region, the area of the semiconductor integrated circuit device can be reduced by the portion of the plurality of voltage supply circuits, compared with the case of being placed in the same region. When some of the plurality of voltage supply circuits are placed in the same region while the remainder being provided in a different region, a trade-off between the above advantages can be considered.

The semiconductor integrated circuit device of the embodiment of the present invention may further include a temperature measurement circuit configured to measure a temperature state, wherein the voltage control signal generation circuit may set, for the voltage supply circuit, a voltage with which the leakage current in the circuit is minimized based on a measurement result of the temperature measurement circuit and evaluation results on a data retention characteristic and leakage current of the semiconductor integrated circuit.

With the above configuration, the set voltage can be changed with change in temperature state, and thus the leakage reduction effect increases.

In the semiconductor integrated circuit device of the embodiment of the present invention, a data retention characteristic and a leakage current characteristic may be acquired immediately before a predetermined data retention operation of the circuit, to perform the voltage setting.

With the above configuration, the number of times of acquisition of the data retention characteristic and the leakage current characteristic can be reduced, permitting reduction in influence on the processing time performance of the circuit.

In the semiconductor integrated circuit device of the embodiment of the present invention, a data retention characteristic and a leakage current characteristic may be acquired periodically, to perform the voltage setting.

With the above configuration, it is possible to set a voltage value including degradation in data retention characteristic caused by degradation in transistor characteristics with time. This permits improvement in data retention even when the transistor characteristics degrade with time.

In the semiconductor integrated circuit device of the embodiment of the present invention, a data retention characteristic and a leakage current characteristic may be acquired when temperature change exceeds a set change amount, to perform the voltage setting.

With the above configuration, it is possible to set a voltage value including a change in data retention characteristic with temperature change. This permits improvement in data retention even when the temperature changes.

As described above, according to the present invention, data retention can be improved, and also the leakage current can be reduced, during power supply control, substrate control, or both power supply and substrate control of a semiconductor chip.

### BRIEF DESCRIPTION OF THE DRAWINGS

FIG. 1 is a view showing a configuration of a semiconductor integrated circuit device of the present invention.

FIG. 2 shows an example of evaluation of the leakage current and the data retention characteristic.

FIG. 3 is a view showing a configuration of a semiconductor integrated circuit device of the second embodiment.

FIG. 4 is a view showing an example of the configuration of a semiconductor integrated circuit device of the third embodiment.

FIG. 5 is a view showing another example of the configuration of the semiconductor integrated circuit device of the third embodiment.

FIG. 6 is a view showing yet another example of the configuration of the semiconductor integrated circuit device of the third embodiment.

FIG. 7 is a view showing yet another example of the configuration of the semiconductor integrated circuit device of the third embodiment.

FIG. 8 is a view showing yet another example of the configuration of the semiconductor integrated circuit device of the third embodiment.

FIG. 9 is a view showing a configuration of a semiconductor integrated circuit device of the fourth embodiment.

FIG. 10 is a view showing an example of control timing.

FIG. 11 is a view showing another example of control timing.

FIG. 12 is a view showing yet another example of control timing.

FIG. 13 is a schematic view of a communication apparatus provided with a semiconductor integrated circuit device of the present invention.

FIG. 14 is a schematic view of an AV apparatus provided with a semiconductor integrated circuit device of the present invention.

FIG. 15 is a schematic view of a mobile vehicle provided with a semiconductor integrated circuit device of the present invention.

### DETAILED DESCRIPTION

Example embodiments of the present invention will be described hereinafter with reference to the drawings.

### First Embodiment

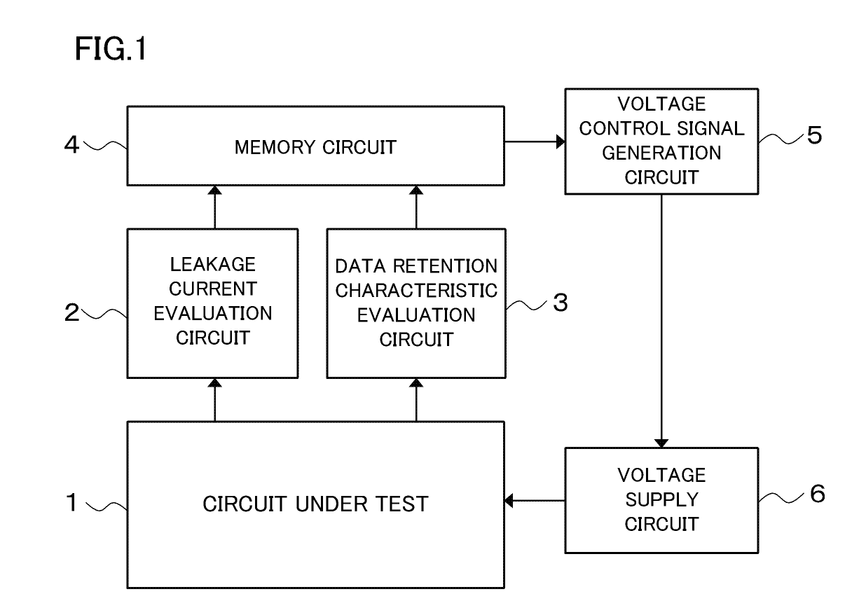

FIG. 1 shows a configuration of a semiconductor integrated circuit device of the present invention. A circuit 1 represents a circuit region under test where data retention operation is performed. The data retention operation as used herein refers to an operation of retaining data required when the power supply voltage to the circuit 1 is reduced for reducing the leakage current, for example. Examples of a circuit that retains data include a flipflop, a SRAM, and a cache. A leakage current evaluation circuit 2 is a circuit that measures the leakage current in the circuit 1: it evaluates the leakage current directly without use of a monitor circuit. A data retention characteristic evaluation circuit 3 is a circuit that evaluates the data retention characteristic of the data retaining circuit in the circuit 1. The circuits 2 and 3 respectively acquire the leakage current characteristic and the data retention characteristic under the same specified voltage condition. The specified evaluation voltages at the acquisition of such data are given to a voltage supply circuit 6 from a voltage control signal generation circuit 5 or from outside the semiconductor chip.

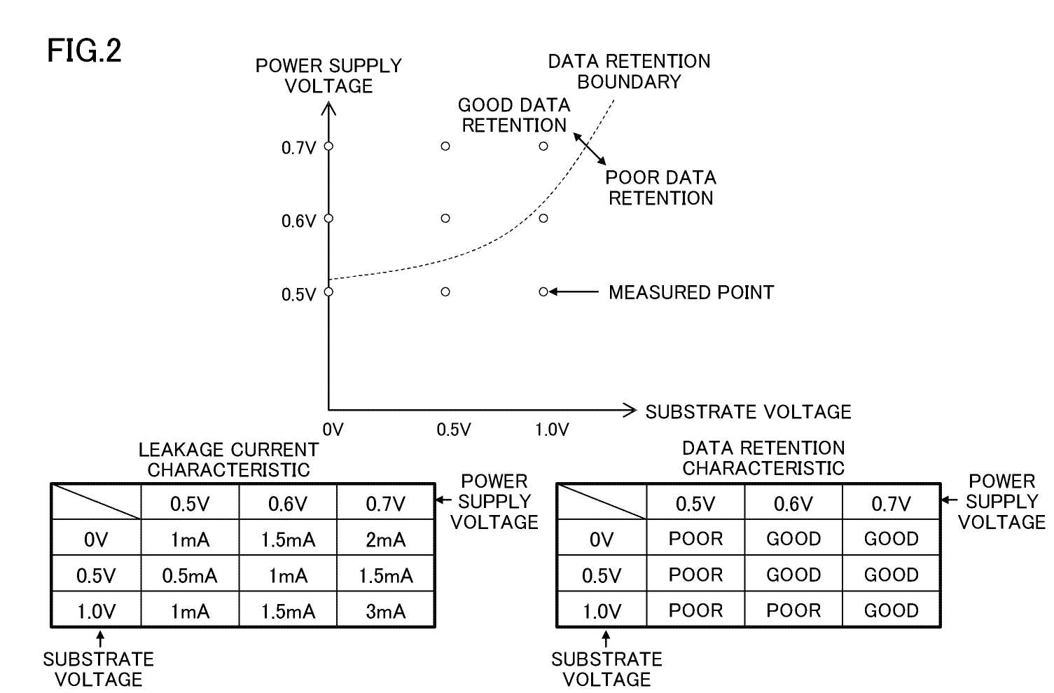

FIG. 2 shows an example of the evaluation results. In the graph, the y-axis represents the power supply voltage and the x-axis represents the substrate voltage. In this example, the measured voltage points are nine (marked by the white circles “◯” in FIG. 2). In the tables, shown are the leakage current characteristic and the determination result on whether data retention is good or not (GOOD: good data retention, POOR: poor data retention) at each measured voltage point. From these tables, it is possible to find out a set of voltages with which the leakage current is minimized and data can be retained. In the illustrated example, such a set of voltages are a power supply voltage of 0.6 V and a substrate voltage of 0.5 V. Note that the substrate voltage refers to a reverse bias acting in a direction of increasing Vt.

To add information on the leakage current characteristic, the reason why the leakage current increases with increase of the substrate voltage is that the increase rate of the junction leakage is larger than the decrease rate of the subthreshold leakage. The subthreshold leakage and the junction leakage have a feature of varying with the process finished state and the set Vt, the temperature, the power supply voltage, and the substrate voltage in the circuit. It is very difficult to set voltages with which the leakage current is minimized, considering such variation factors. Therefore, a margin must be provided when the voltage setting is performed by fixing the voltages in the initial state. According to the embodiment of the present invention, however, optimum voltage setting for minimizing the leakage current is achieved by evaluating the characteristics of the circuit 1. Naturally, the larger the number of measured voltage points, the more the leakage current can be reduced by the voltage setting.

A memory circuit 4 is a circuit that retains the measurement results on the leakage current and the data retention characteristic. The voltage control signal generation circuit 5 reads the evaluation result data stored in the memory circuit 4, and generates a voltage control signal based on the read data and outputs the signal to the voltage supply circuit 6. The voltage supply circuit 6 applies voltages to the circuit 1.

With the circuit configuration described above, it is possible to apply, to the circuit 1, voltages with which the leakage current is minimized and data can be retained.

### Second Embodiment

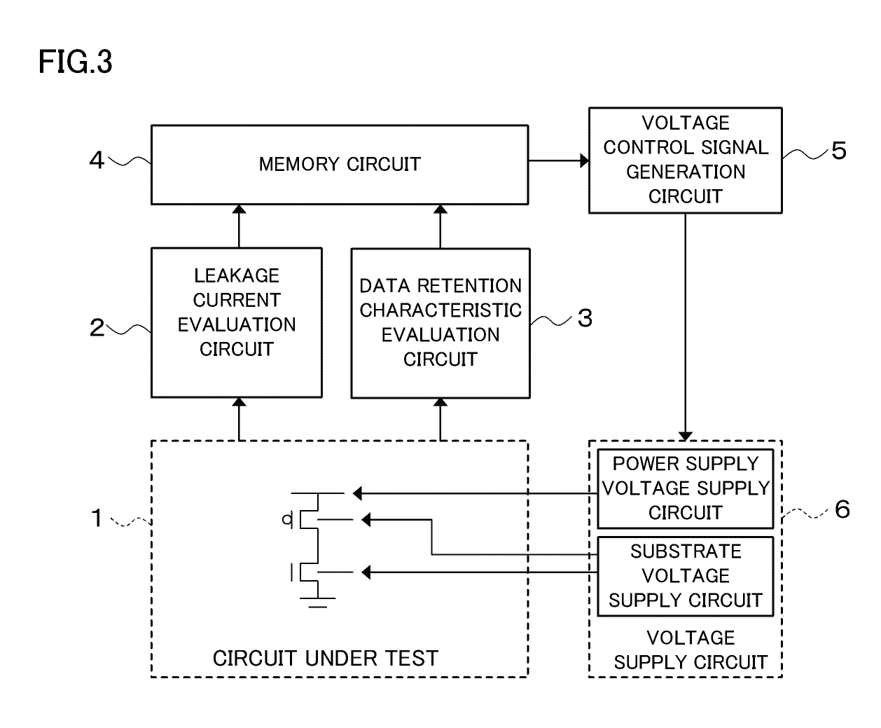

FIG. 3 shows details of the voltage supply circuit 6. Means of reducing the leakage current in the circuit 1 include reducing the power supply voltage and applying the substrate voltage. The voltage supply circuit 6 includes a power supply voltage supply circuit that supplies the power supply voltage to the circuit 1 and a substrate voltage supply circuit that supplies the substrate voltage to the circuit 1, thereby to allow voltage setting of only the power supply voltage, only the substrate voltage, or both voltages. As for the substrate voltage, only an Nch substrate voltage, only a Pch substrate voltage, or both voltages may be controlled. As the way of supply of the power supply voltage, a source clamp technique where the source voltage is increased to decrease the source-drain voltage difference, etc. are also applicable. Details of the control are the same as those described in the first embodiment and thus omitted here.

### Third Embodiment

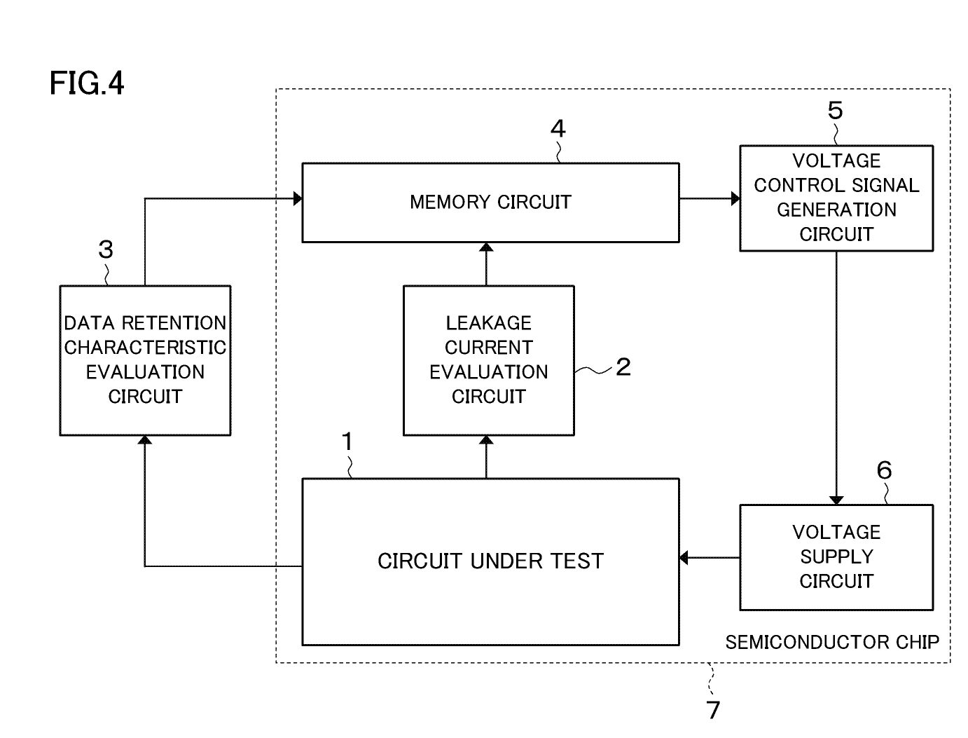

FIG. 4 shows a configuration where the data retention characteristic evaluation circuit 3 is placed in a region outside a semiconductor chip 7. The semiconductor chip 7 includes the circuit 1, the leakage current evaluation circuit 2, the memory circuit 4, the voltage control signal generation circuit 5, and the voltage supply circuit 6. Specific examples of the data retention characteristic evaluation circuit 3 placed outside the semiconductor chip 7 include a semiconductor chip for evaluation included in a packaged product, a tester, etc. With such a semiconductor chip for evaluation included in a packaged product, evaluation can be performed when necessary. In the case of evaluation with a tester, the memory circuit 4 must be nonvolatile, and the evaluation results will be written in the memory circuit 4 before shipment.

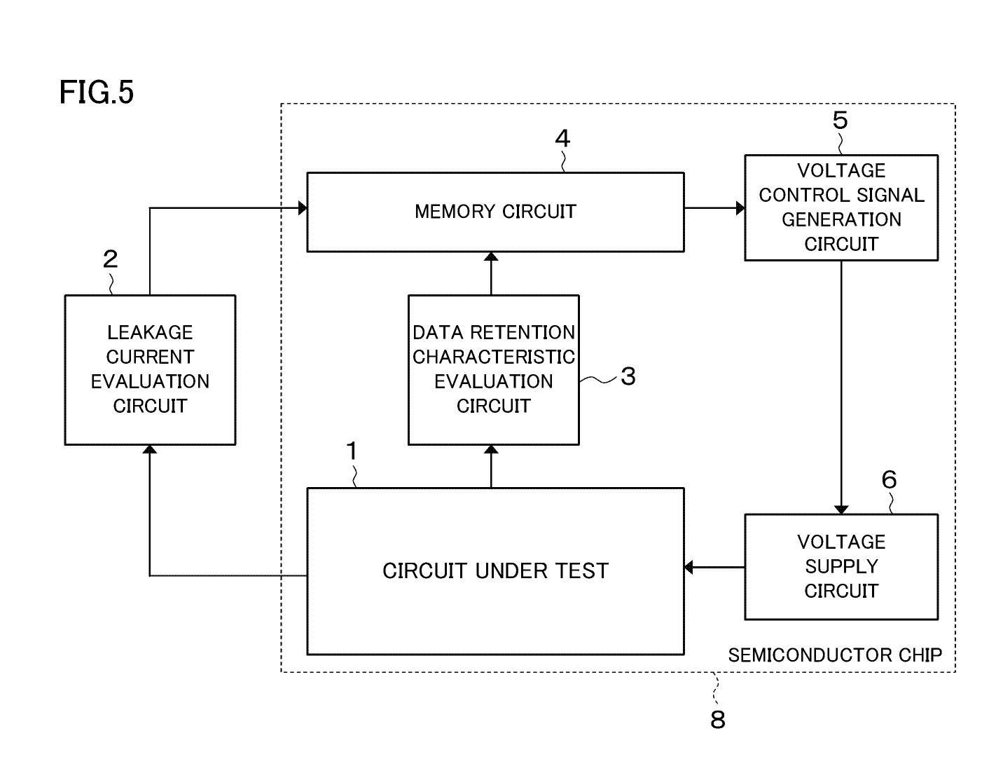

FIG. 5 shows another configuration where the leakage current evaluation circuit 2 is placed in a region outside a semiconductor chip 8. The semiconductor chip 8 includes the circuit 1, the data retention characteristic evaluation circuit 3, the memory circuit 4, the voltage control signal generation circuit 5, and the voltage supply circuit 6. Specific examples of the leakage current evaluation circuit 2 placed outside the semiconductor chip 8 may be similar to those described above with reference to FIG. 4. This configuration can also be one of options from the standpoint of cost elements such as the area and the number of steps.

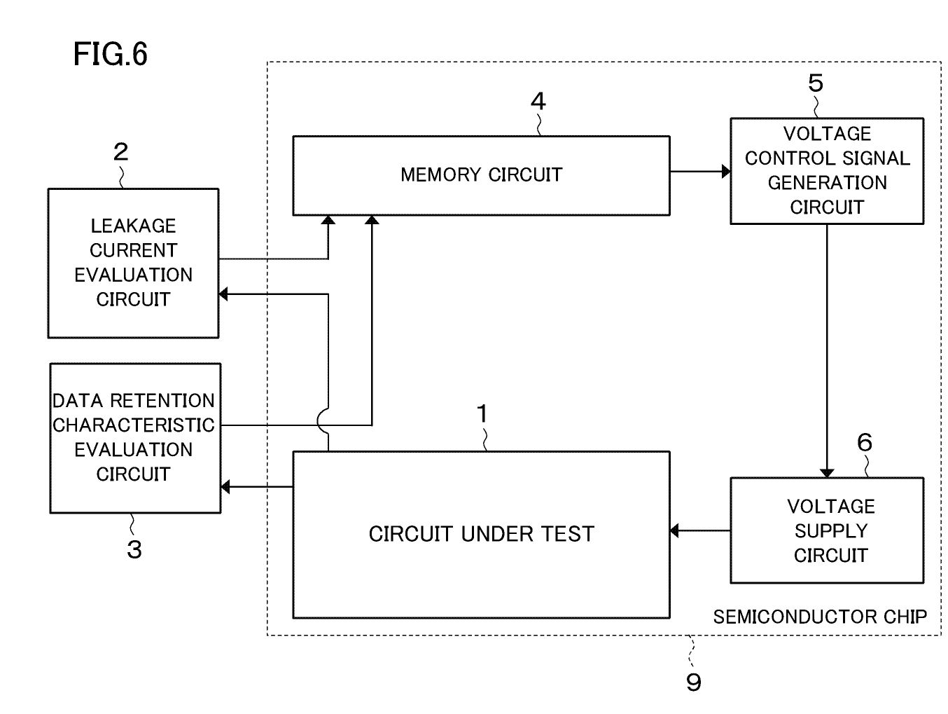

FIG. 6 shows yet another configuration where the leakage current evaluation circuit 2 and the data retention characteristic evaluation circuit 3 are placed in a region outside a semiconductor chip 9. The semiconductor chip 9 includes the circuit 1, the memory circuit 4, the voltage control signal generation circuit 5, and the voltage supply circuit 6. Specific examples of the leakage current evaluation circuit 2 and the data retention characteristic evaluation circuit 3 placed outside the semiconductor chip 9 may be similar to those described above with reference to FIG. 4. This configuration can also be one of options from the standpoint of cost elements such as the area and the number of steps.

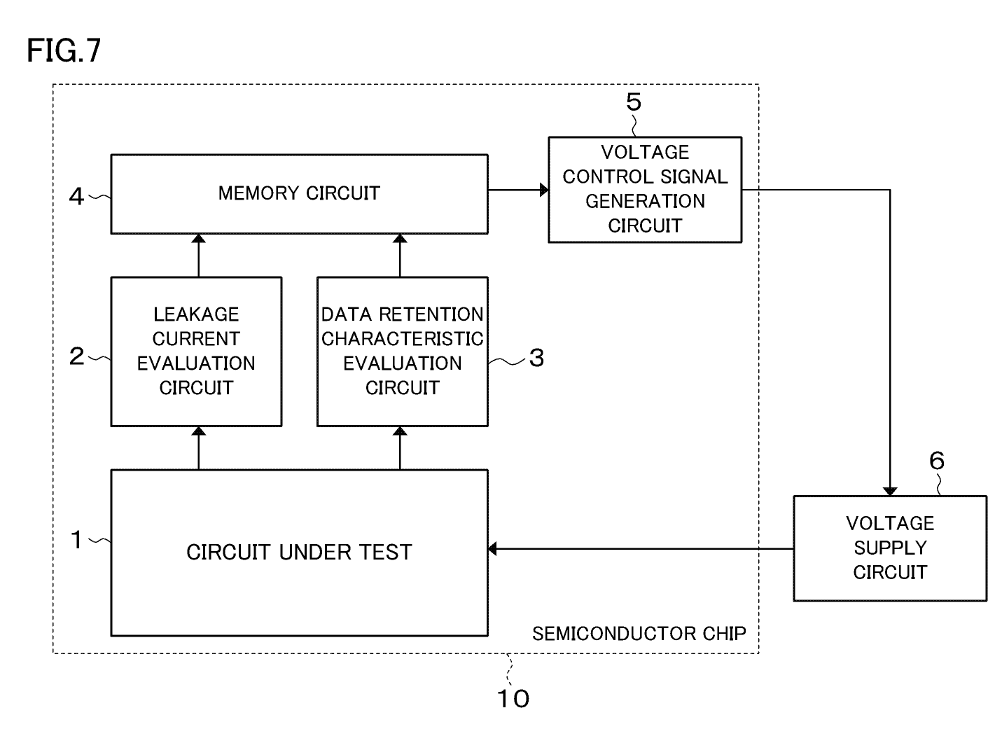

FIG. 7 shows yet another configuration where the voltage supply circuit 6 is placed in a region outside a semiconductor chip 10. The semiconductor chip 10 includes the circuit 1, the leakage current evaluation circuit 2, the data retention characteristic evaluation circuit 3, the memory circuit 4, and the voltage control signal generation circuit 5. Specific examples of the voltage supply circuit 6 placed outside the semiconductor chip 10 may be similar to those described above with reference to FIG. 4. This configuration can also be one of options from the standpoint of cost elements such as the area and the number of steps.

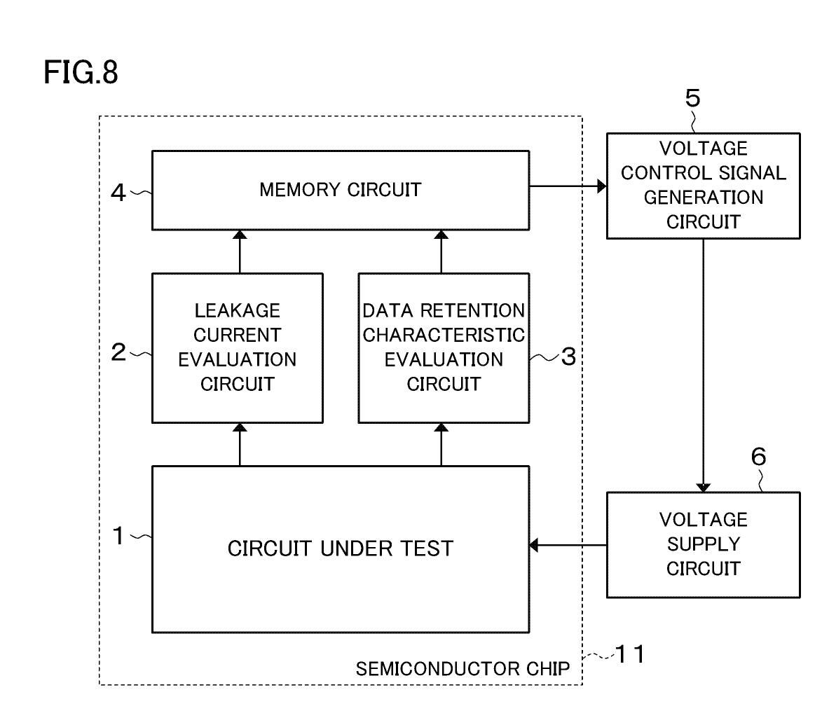

FIG. 8 shows yet another configuration where the voltage control signal generation circuit 5 and the voltage supply circuit 6 are placed in a region outside a semiconductor chip 11. The semiconductor chip 11 includes the circuit 1, the leakage current evaluation circuit 2, the data retention characteristic evaluation circuit 3, and the memory circuit 4. Specific examples of the voltage control signal generation circuit 5 and the voltage supply circuit 6 provided outside the semiconductor chip 11 may be similar to those described above with reference to FIG. 4. This configuration can also be one of options from the standpoint of cost elements such as the area and the number of steps. The voltage control signal generation circuit 5 may be placed in a dedicated semiconductor chip for power management.

The configurations are not limited to those described above, but each of the circuit 1, the leakage current evaluation circuit 2, the data retention characteristic evaluation circuit 3, the memory circuit 4, the voltage control signal generation circuit 5, and the voltage supply circuit 6 may include a plurality of such circuits, and some of the plurality of such circuits may be placed inside the semiconductor chip while the remainder being placed outside the semiconductor chip, as necessary.

### Fourth Embodiment

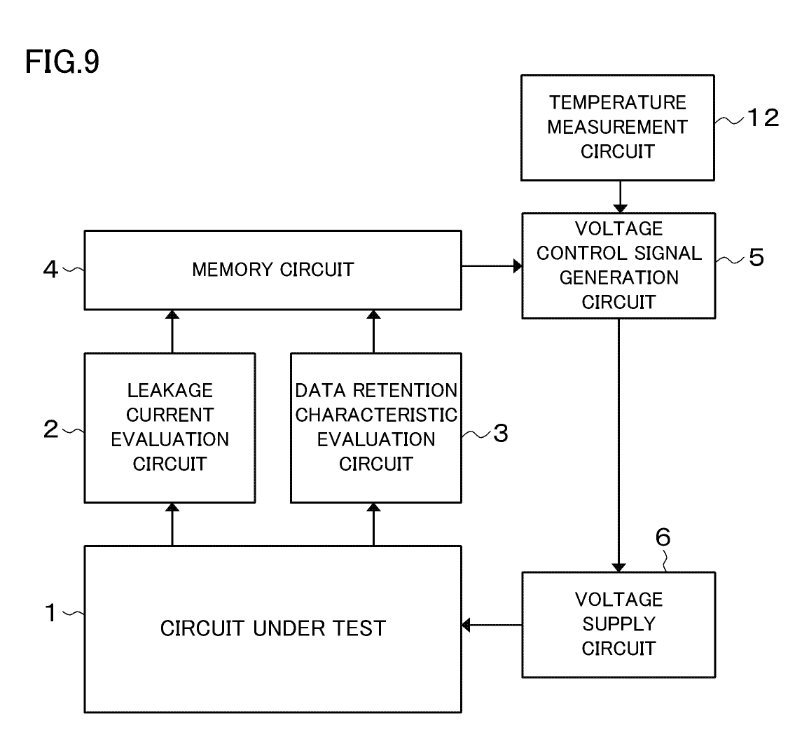

FIG. 9 shows a circuit configuration including a temperature measurement circuit 12 in addition to the components of the semiconductor integrated circuit device of FIG. 1. The temperature measurement circuit 12 may be placed inside or outside the semiconductor chip. The data retention characteristic and the leakage current, which vary with the temperature state, are measured previously under a plurality of temperature conditions. This measurement may be performed by a tester, or performed after the semiconductor chip is packaged into a product. By referring to the relationship between the temperature and each of the data retention characteristic and the leakage current, the voltage setting is changed based on the temperature information from the temperature measurement circuit 12, thereby to permit optimum voltage setting according to the temperature.

### Fifth Embodiment

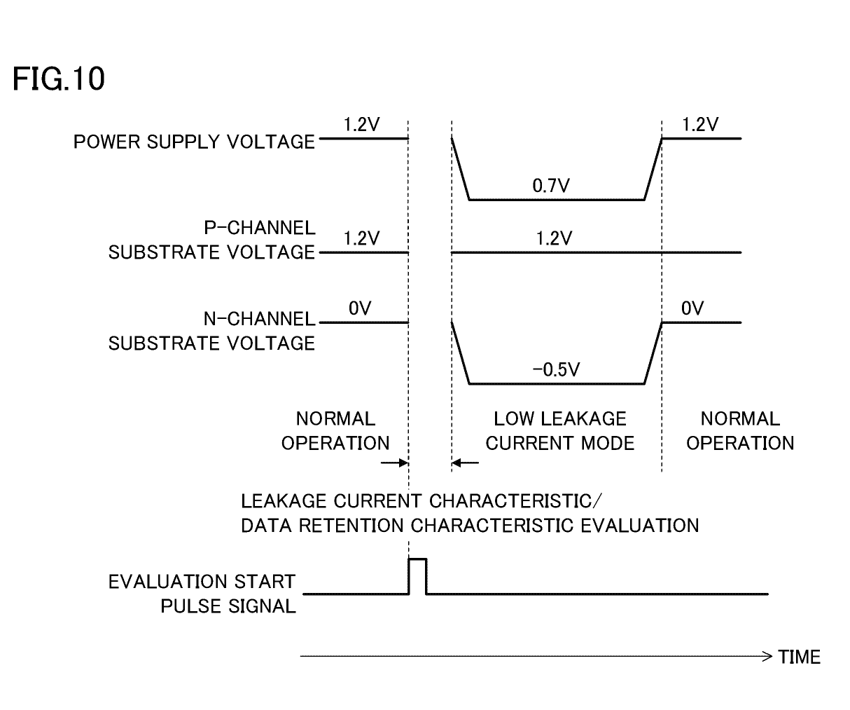

FIG. 10 shows the timing of evaluation of the data retention characteristic and the leakage current. The leakage current and the data retention characteristic are evaluated immediately before the shift to the data retention operation for reducing the leakage current. The evaluation time is preferably within several seconds for which neither temperature change nor transistor degradation will occur. When the data retention time is long, the data retention characteristic and the leakage current may change due to temperature change and transistor degradation during the data retention time. In such a case, therefore, it is desirable to perform the evaluation even during the data retention operation. An evaluation start pulse signal may be prepared based on a control signal used for the shift to the data retention operation.

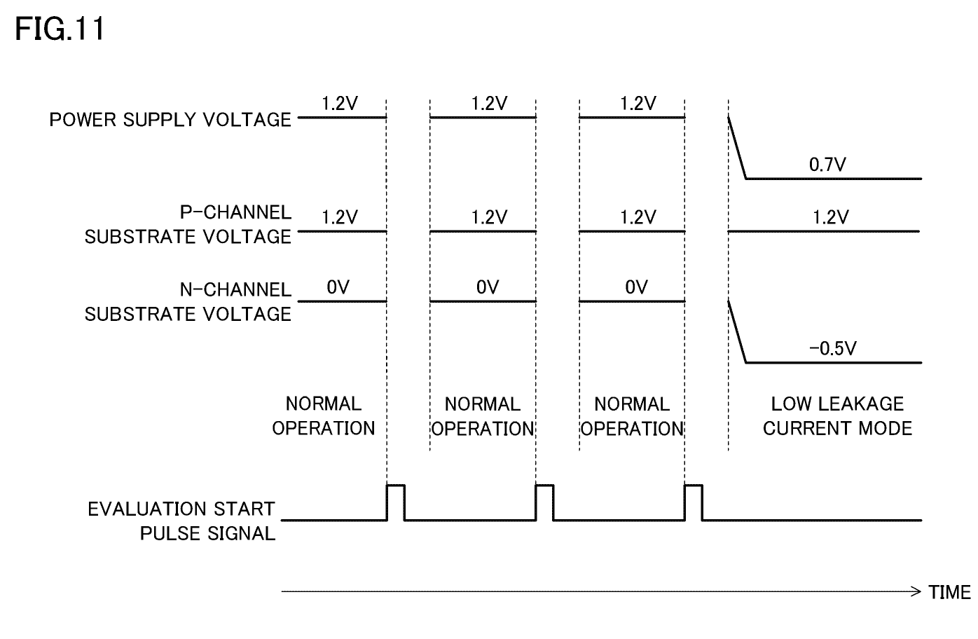

FIG. 11 shows periodic evaluation of the data retention characteristic and the leakage current. The time interval at which the leakage current and the data retention characteristic change due to transistor degradation is measured previously, and the evaluation is performed periodically at such intervals, thereby to permit voltage setting with no consideration given to transistor degradation. The evaluation start pulse signal may be prepared from a clock inside the semiconductor chip or a fixed-interval signal outside the semiconductor chip.

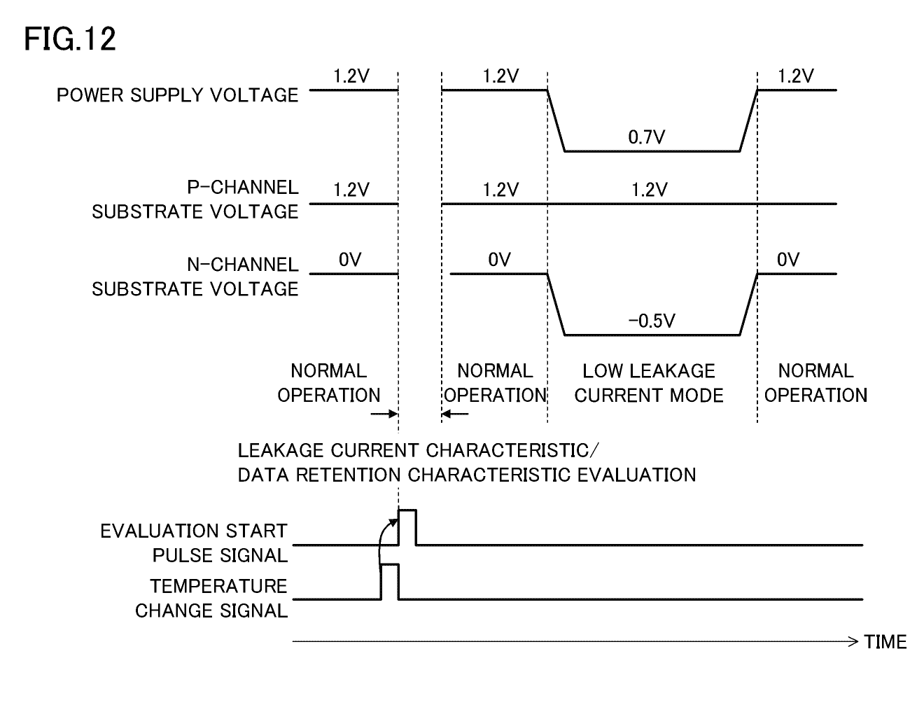

FIG. 12 shows evaluation of the data retention characteristic and the leakage current performed at the occurrence of a given temperature change in the semiconductor chip. The data retention characteristic and the leakage current change due to temperature change as described above. A temperature change signal may be prepared from a signal generated by a temperature sensor inside the semiconductor chip or a temperature measuring device outside the semiconductor chip.

(Applications)

The semiconductor integrated circuit device of an embodiment of the present invention is applicable to information equipment in general, such as PDAs and portable music players.

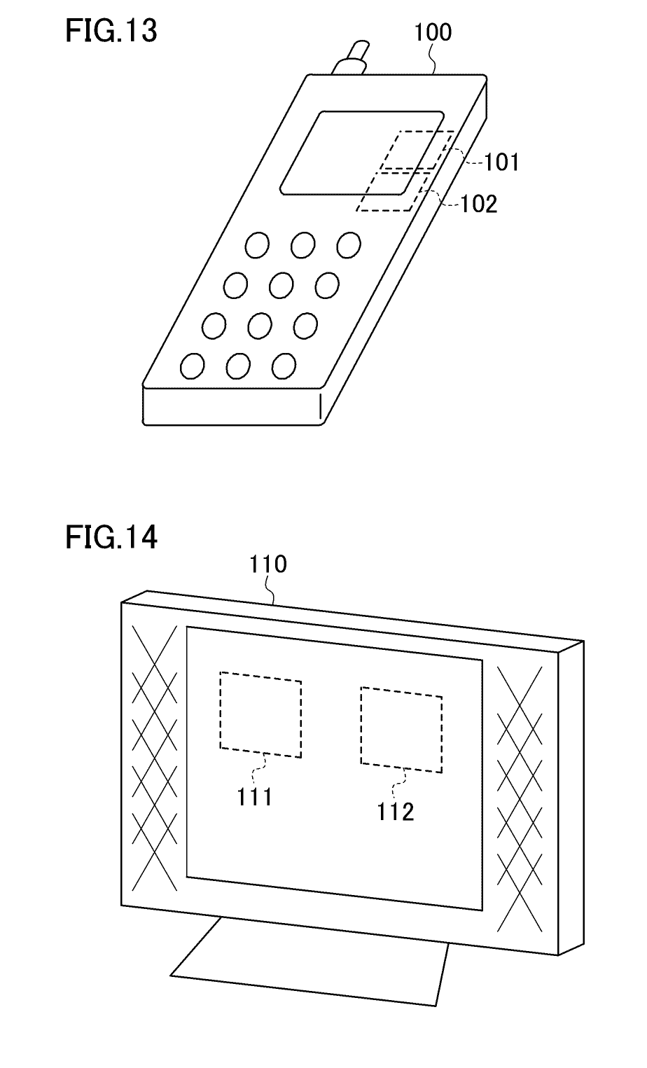

FIG. 13 shows an outline of a communication apparatus provided with the semiconductor integrated circuit device of an embodiment of the present invention. A mobile phone 100 includes a baseband LSI 101 and an application LSI 102 each having the configuration of FIG. 1. Since the semiconductor integrated circuit device of an embodiment of the present invention can reduce power compared with the conventional ones, power reduction can also be achieved in the baseband LSI 101, the application LSI 102, and thus the mobile phone 100 provided with such LSIs. The semiconductor integrated circuit device of an embodiment of the present invention is applicable to communication apparatuses in general, such as transmitters, receivers, and modems in communication systems. In other words, according to the present invention, power reduction can be achieved in all communication apparatuses irrespective of whether wired or wireless, whether optical communication or telecommunication, and whether digital or analog.

FIG. 14 shows an outline of an AV apparatus provided with the semiconductor integrated circuit device of an embodiment of the present invention. A TV receiver 110 includes an audio/video processing LSI 111 and a display/sound source control LSI 112 each having the configuration of FIG. 1. Since the semiconductor integrated circuit device of an embodiment of the present invention can reduce power compared with the conventional ones, power reduction can also be achieved in the audio/video processing LSI 111, the display/sound source control LSI 112, and thus the TV receiver 110 provided with such LSIs. The semiconductor integrated circuit device of an embodiment of the present invention is applicable to AV apparatuses in general, such as optical disc recorders, digital still cameras, and digital video cameras.

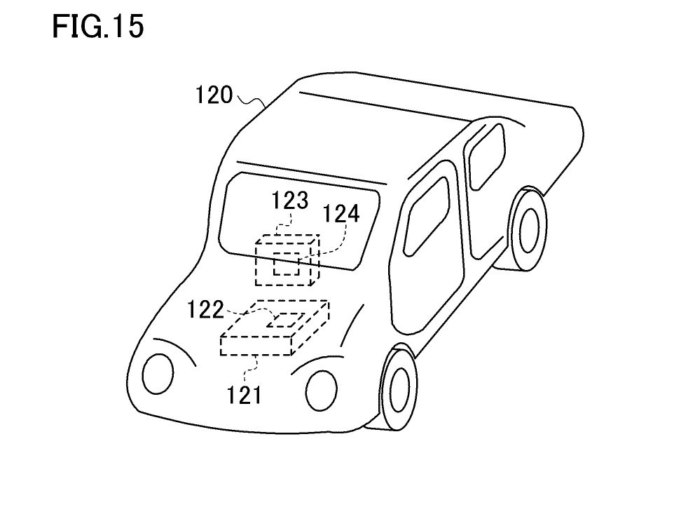

FIG. 15 shows an outline of a mobile vehicle provided with the semiconductor integrated circuit device of an embodiment of the present invention. An automobile 120 includes an electronic control unit (ECU) 121, which in turn includes an engine/transmission control LSI 122 having the configuration of FIG. 1. The automobile 120 also includes a navigation apparatus 123, which in turn includes a navigation LSI 124 having the configuration of FIG. 1. Since the semiconductor integrated circuit device of an embodiment of the present invention can reduce power compared with the conventional ones, power reduction can also be achieved in the engine/transmission control LSI 122 and thus the ECU 121 provided with this LSI. Similarly, power reduction can be achieved in the navigation LSI 124 and thus the navigation apparatus 123 provided with this LSI. With the reduced power in the ECU 121, reduction in electric power can also be achieved in the automobile 120. The semiconductor integrated circuit device of an embodiment of the present invention is applicable to mobile vehicles in general provided with an engine, a motor, etc. as a power source, such as trains and airplanes.

In the semiconductor integrated circuit device of an embodiment of the present invention, voltages with which the leakage current is minimized and data retention is improved can be set for each semiconductor chip. Thus, the present invention is useful, in particular, for semiconductor chips mounted in mobile products having strict power requirements.

The present invention is not limited to the embodiments described above but can be embodied in other various forms without departing from the spirit or major features thereof. The foregoing embodiments are merely illustrative in every aspect and should not be construed restrictively. The scope of the invention is to be defined by the appended claims rather than by the details of the foregoing description. All of modifications and changes falling within the scope of equivalence of the appended claims are also intended to be within the scope of the invention.

What is claimed is:

1. A semiconductor integrated circuit device, comprising:
a circuit required to be in a data retaining state;
a data retention characteristic evaluation circuit configured to measure the data retaining state of the circuit;
a leakage current evaluation circuit configured to measure a leakage current in the circuit;
a voltage control signal generation circuit configured to control a voltage supply circuit for the circuit; and
a memory circuit configured to store measurement results of the leakage current evaluation circuit and the data retention characteristic evaluation circuit,
wherein
the voltage control signal generation circuit sets, for the voltage supply circuit, a voltage with which the leakage current in the circuit is minimized, based on data stored in the memory circuit.

2. The semiconductor integrated circuit device of claim 1, wherein
the voltage value set by the voltage control signal generation circuit for the voltage supply circuit is a source-drain voltage.

3. The semiconductor integrated circuit device of claim 1, wherein
the voltage value set by the voltage control signal generation circuit for the voltage supply circuit is a source-substrate voltage.

4. The semiconductor integrated circuit device of claim 1, wherein
the circuit, the leakage current evaluation circuit, the memory circuit, the voltage control signal generation circuit, and the voltage supply circuit are placed on a same semiconductor chip, and
the data retention characteristic evaluation circuit is placed in a region different from the semiconductor chip, and transfers a data retention characteristic to the memory circuit from the different region.

5. The semiconductor integrated circuit device of claim 1, wherein
the circuit, the data retention characteristic evaluation circuit, the memory circuit, the voltage control signal generation circuit, and the voltage supply circuit are placed on a same semiconductor chip, and
the leakage current evaluation circuit is placed in a region different from the semiconductor chip, and transfers a leakage current characteristic to the memory circuit from the different region.

6. The semiconductor integrated circuit device of claim 1, wherein
the circuit, the memory circuit, the voltage control signal generation circuit, and the voltage supply circuit are placed on a same semiconductor chip, and
the data retention characteristic evaluation circuit and the leakage current evaluation circuit are placed in a region different from the semiconductor chip, and transfers a data retention characteristic and a leakage current characteristic to the memory circuit from the different region.

7. The semiconductor integrated circuit device of claim 1, wherein
the circuit, the leakage current evaluation circuit, the data retention characteristic evaluation circuit, the memory circuit, and the voltage control signal generation circuit are placed on a same semiconductor chip, and
the voltage supply circuit is placed in a region different from the semiconductor chip.

8. The semiconductor integrated circuit device of claim 1, wherein
the voltage supply circuit comprises a plurality of voltage supply circuits,
the circuit, the leakage current evaluation circuit, the data retention characteristic evaluation circuit, the memory circuit, and the voltage control signal generation circuit are placed on a same semiconductor chip, and
the entire of the plurality of voltage supply circuits are placed on the semiconductor chip or in a region different from the semiconductor chip, or otherwise some of the plurality of voltage supply circuits are placed on the semiconductor chip while the remainder being placed in a region different from the semiconductor chip.

9. The semiconductor integrated circuit device of claim 1, wherein
the circuit, the leakage current evaluation circuit, the data retention characteristic evaluation circuit, and the memory circuit are placed on a same semiconductor chip, and
the voltage control signal generation circuit and the voltage supply circuit are placed in a region different from the semiconductor chip.

10. The semiconductor integrated circuit device of claim 1, further comprising:
a temperature measurement circuit configured to measure a temperature state,
wherein
the voltage control signal generation circuit sets, for the voltage supply circuit, a voltage with which the leakage current in the circuit is minimized, based on a measurement result of the temperature measurement circuit and evaluation results on a data retention characteristic and leakage current of the semiconductor integrated circuit.

11. The semiconductor integrated circuit device of claim 1, wherein a data retention characteristic and a leakage current characteristic are acquired immediately before predetermined data retention operation of the circuit, to perform the voltage setting.

12. The semiconductor integrated circuit device of claim 1, wherein a data retention characteristic and a leakage current characteristic are acquired periodically, to perform the voltage setting.

13. The semiconductor integrated circuit device of claim 1, wherein a data retention characteristic and a leakage current characteristic are acquired when temperature change exceeds a set change amount, to perform the voltage setting.

14. A communication apparatus provided with the semiconductor integrated circuit device of claim 1.

15. An AV apparatus provided with the semiconductor integrated circuit device of claim 1.

16. A mobile vehicle provided with the semiconductor integrated circuit device of claim 1.
